(19) United States
(12) Patent Application Publication
(10) Pub. No.: US 2025/0283946 A1
(43) Pub. Date: Sep. 11, 2025

(54) REFERENCE ELECTRODE MANAGEMENT FOR A BATTERY CELL

(71) Applicant: GM Global Technology Operations LLC, Detroit, MI (US)

(72) Inventors: Brian J. Koch, Berkley, MI (US); Jing Gao, Rochester, MI (US); Anne Zhang, Troy, MI (US); Alok Warey, Novi, MI (US)

(21) Appl. No.: 18/599,743

(22) Filed: Mar. 8, 2024

(51) Int. Cl. G01R 31/3835; B60L 58/13; G01R 19/12; G01R 19/165; G01R 31/36; G01R 31/385; G01R 31/388; H01M 10/42; H01M 10/48

(52) U.S. Cl. CPC G01R 31/3835; B60L 58/13; G01R 19/12; G01R 19/16542; G01R 31/3648; G01R 31/386; G01R 31/388; H01M 10/48; H01M 2010/4271

(57) ABSTRACT

A method for regulating a state of charge of a reference electrode in a battery cell may include determining a reference electrode state of charge (SOC) of the reference electrode. The battery cell includes an anode, a cathode, and the reference electrode. The reference electrode is disposed between the anode and the cathode. The method further may include comparing the reference electrode SOC to at least a predetermined low SOC threshold. The method further may include adjusting the reference electrode SOC in response to determining that the reference electrode SOC is less than or equal to the predetermined low SOC threshold or that the reference electrode SOC is greater than or equal to a predetermined high SOC threshold.

### INTRODUCTION

The present disclosure relates to systems and methods for battery management for a battery cell, and more particularly, to systems and methods for regulating a state of charge of a reference electrode in a battery cell.

To increase performance, ease-of-use, and usable life, it is advantageous to estimate a state of charge (SOC) of a battery cell. Generally, the SOC of a battery cell is not a directly measurable quantity because it is dependent on electrochemical processes occurring within the battery cell. Thus, mathematical models are used to estimate the SOC of the battery cell based on directly measurable quantities such as voltages and/or currents. The mathematical models used to estimate the SOC of the battery cell are often highly non-linear and may be affected by measurement error. Thus, it is advantageous to provide a reference electrode within the battery cell to provide a reference voltage for accurate measurement of voltages of components of the battery cell. However, use of the reference electrode to perform measurements may result in depletion of a SOC of the reference electrode, and thus variation in the reference voltage.

Thus, while battery management systems and methods achieve their intended purpose, there is a need for a new and improved system and method for regulating a state of charge of a reference electrode in a battery cell.

### SUMMARY

According to several aspects, a method for regulating a state of charge of a reference electrode in a battery cell is provided. The method may include determining a reference electrode state of charge (SOC) of the reference electrode. The battery cell includes an anode, a cathode, and the reference electrode. The reference electrode is disposed between the anode and the cathode. The method further may include comparing the reference electrode SOC to at least a predetermined low SOC threshold. The method further may include adjusting the reference electrode SOC in response to determining that the reference electrode SOC is less than or equal to the predetermined low SOC threshold or that the reference electrode SOC is greater than or equal to a predetermined high SOC threshold.

In another aspect of the present disclosure, determining the reference electrode SOC further may include charging the reference electrode and measuring an amount of charge added to the reference electrode. Determining the reference electrode SOC further may include measuring an anode reference voltage while charging the reference electrode. Determining the reference electrode SOC further may include determining the reference electrode SOC based at least in part on the anode reference voltage and the amount of charge added to the reference electrode.

In another aspect of the present disclosure, determining the reference electrode SOC based at least in part on the anode reference voltage and the amount of charge added to the reference electrode further may include calculating a first order reference electrode voltage slope. The first order reference electrode voltage slope is a first derivative of the anode reference voltage while charging the reference electrode with respect to the amount of charge added to the reference electrode. Determining the reference electrode SOC based at least in part on the anode reference voltage and the amount of charge added to the reference electrode further may include determining the reference electrode SOC based at least in part on the first order reference electrode voltage slope.

In another aspect of the present disclosure, determining the reference electrode SOC based at least in part on the first order reference electrode voltage slope further may include determining the reference electrode SOC to be less than or equal to the predetermined low SOC threshold in response to determining that the first order reference electrode voltage slope is greater than or equal to a predetermined first order reference electrode voltage slope low threshold and that the first order reference electrode voltage slope is decreasing. Determining the reference electrode SOC based at least in part on the first order reference electrode voltage slope further may include determining the reference electrode SOC to be greater than or equal to the predetermined high SOC threshold in response to determining that the first order reference electrode voltage slope is greater than or equal to the predetermined first order reference electrode voltage slope high threshold and that the first order reference electrode voltage slope is increasing.

In another aspect of the present disclosure, adjusting the reference electrode SOC further may include charging the reference electrode in response to determining that the reference electrode SOC is less than or equal to the predetermined low SOC threshold. The reference electrode is charged until the first order reference electrode voltage slope is greater than or equal to the predetermined first order reference electrode voltage slope high threshold and the first order reference electrode voltage slope is increasing.

In another aspect of the present disclosure, determining the reference electrode SOC based at least in part on the anode reference voltage and the amount of charge added to the reference electrode further may include calculating a second order reference electrode voltage slope. The second order reference electrode voltage slope is a second derivative of the anode reference voltage while charging the reference electrode with respect to the amount of charge added to the reference electrode. Determining the reference electrode SOC based at least in part on the anode reference voltage and the amount of charge added to the reference electrode further may include determining the reference electrode SOC based at least in part on the second order reference electrode voltage slope.

In another aspect of the present disclosure, determining the reference electrode SOC based at least in part on the second order reference electrode voltage slope further may include determining the reference electrode SOC to be less than or equal to the predetermined low SOC threshold in response to determining that the second order reference electrode voltage slope is less than or equal to a predetermined second order reference electrode voltage slope low threshold. Determining the reference electrode SOC based at least in part on the second order reference electrode voltage slope further may include determining the reference electrode SOC to be greater than or equal to the predetermined high SOC threshold in response to determining that the second order reference electrode voltage slope is greater than or equal to a predetermined second order reference electrode voltage slope high threshold.

In another aspect of the present disclosure, adjusting the reference electrode SOC further may include charging the reference electrode in response to determining that the reference electrode SOC is less than or equal to the predetermined low SOC threshold. The reference electrode is charged until the second order reference electrode voltage slope is greater than or equal to the predetermined second order reference electrode voltage slope high threshold.

In another aspect of the present disclosure, determining the reference electrode SOC further may include tracking an elapsed time since a previous charging process of the reference electrode. Determining the reference electrode SOC further may include calculating an amount of lost charge from the reference electrode based at least in part on the elapsed time and a predetermined reference electrode discharge rate of the reference electrode. Determining the reference electrode SOC further may include calculating the reference electrode SOC based at least in part on the amount of lost charge.

In another aspect of the present disclosure, adjusting the reference electrode SOC further may include charging the reference electrode in response to determining that the reference electrode SOC is less than or equal to the predetermined low SOC threshold. The reference electrode is charged until the amount of lost charge is returned to the reference electrode.

According to several aspects, a system for regulating a state of charge of a reference electrode in a battery cell is provided. The system may include the battery cell including an anode, a cathode, and the reference electrode. The reference electrode is disposed between the anode and the cathode. The system further may include a reference electrode management system in electrical communication with the battery cell, the reference electrode management system including a controller. The controller is programmed to determine a reference electrode state of charge (SOC) of the reference electrode. The controller is further programmed to compare the reference electrode SOC to at least a predetermined low SOC threshold. The controller is further programmed to adjust the reference electrode SOC in response to determining that the reference electrode SOC is less than or equal to the predetermined low SOC threshold or that the reference electrode SOC is greater than or equal to a predetermined high SOC threshold.

In another aspect of the present disclosure, to determine the reference electrode SOC, the controller is further programmed to charge the reference electrode by allowing a current flow between the cathode and the reference electrode. To determine the reference electrode SOC, the controller is further programmed to measure an amount of charge added to the reference electrode while charging the reference electrode. To determine the reference electrode SOC, the controller is further programmed to measure an anode reference voltage while charging the reference electrode. To determine the reference electrode SOC, the controller is further programmed to determine the reference electrode SOC based at least in part on the anode reference voltage and the amount of charge added to the reference electrode.

In another aspect of the present disclosure, to determine the reference electrode SOC based at least in part on the anode reference voltage and the amount of charge added to the reference electrode, the controller is further programmed to calculate a first order reference electrode voltage slope. The first order reference electrode voltage slope is a first derivative of the anode reference voltage while charging the reference electrode with respect to the amount of charge added to the reference electrode. To determine the reference electrode SOC based at least in part on the anode reference voltage and the amount of charge added to the reference electrode, the controller is further programmed to determine the reference electrode SOC to be less than or equal to the predetermined low SOC threshold in response to determining that the first order reference electrode voltage slope is greater than or equal to a predetermined first order reference electrode voltage slope low threshold and that the first order reference electrode voltage slope is decreasing. To determine the reference electrode SOC based at least in part on the anode reference voltage and the amount of charge added to the reference electrode, the controller is further programmed to determine the reference electrode SOC to be greater than or equal to the predetermined high SOC threshold in response to determining that the first order reference electrode voltage slope is greater than or equal to the predetermined first order reference electrode voltage slope high threshold and that the first order reference electrode voltage slope is increasing.

In another aspect of the present disclosure, to determine the reference electrode SOC based at least in part on the anode reference voltage and the amount of charge added to the reference electrode, the controller is further programmed to calculate a second order reference electrode voltage slope. The second order reference electrode voltage slope is a second derivative of the anode reference voltage while charging the reference electrode with respect to the amount of charge added to the reference electrode. To determine the reference electrode SOC based at least in part on the anode reference voltage and the amount of charge added to the reference electrode, the controller is further programmed to determine the reference electrode SOC to be less than or equal to the predetermined low SOC threshold in response to determining that the second order reference electrode voltage slope is less than or equal to a predetermined second order reference electrode voltage slope low threshold. To determine the reference electrode SOC based at least in part on the anode reference voltage and the amount of charge added to the reference electrode, the controller is further programmed to determine the reference electrode SOC to be greater than or equal to the predetermined high SOC threshold in response to determining that the second order reference electrode voltage slope is greater than or equal to a predetermined second order reference electrode voltage slope high threshold.

In another aspect of the present disclosure, to adjust the reference electrode SOC, the controller is further programmed to charge the reference electrode in response to determining that the reference electrode SOC is less than or equal to the predetermined low SOC threshold. The reference electrode is charged until at least one of: (i) the first order reference electrode voltage slope is greater than or equal to the predetermined first order reference electrode voltage slope low threshold and the first order reference electrode voltage slope is increasing and (ii) the second order reference electrode voltage slope is greater than or equal to the predetermined second order reference electrode voltage slope high threshold.

In another aspect of the present disclosure, to determine the reference electrode SOC, the controller is further programmed to track an elapsed time since a previous charging process of the reference electrode. To determine the reference electrode SOC, the controller is further programmed to calculate an amount of lost charge from the reference electrode based at least in part on the elapsed time and a predetermined reference electrode discharge rate of the reference electrode. To determine the reference electrode SOC, the controller is further programmed to calculate the reference electrode SOC based at least in part on the amount of lost charge.

In another aspect of the present disclosure, to adjust the reference electrode SOC, the controller is further programmed to charge the reference electrode in response to determining that the reference electrode SOC is less than or equal to the predetermined low SOC threshold. The reference electrode is charged until the amount of lost charge is returned to the reference electrode.

According to several aspects, a system for regulating a state of charge of a reference electrode in a battery cell in a vehicle is provided. The system may include the battery cell including an anode, a cathode, and the reference electrode. The reference electrode is disposed between the anode and the cathode. The system further may include a reference electrode management system in electrical communication with the battery cell. The reference electrode management system includes a controller. The controller is programmed to charge the reference electrode by allowing a current flow between the cathode and the reference electrode. The controller is further programmed to measure an amount of charge added to the reference electrode while charging the reference electrode. The controller is further programmed to measure an anode reference voltage while charging the reference electrode. The controller is further programmed to determine a reference electrode SOC based at least in part on the anode reference voltage and the amount of charge added to the reference electrode. The controller is further programmed to compare the reference electrode SOC to at least a predetermined low SOC threshold. The controller is further programmed to adjust the reference electrode SOC in response to determining that the reference electrode SOC is less than or equal to the predetermined low SOC threshold or that the reference electrode SOC is greater than or equal to a predetermined high SOC threshold.

In another aspect of the present disclosure, to determine the reference electrode SOC based at least in part on the anode reference voltage and the amount of charge added to the reference electrode, the controller is further programmed to calculate a second order reference electrode voltage slope. The second order reference electrode voltage slope is a second derivative of the anode reference voltage while charging the reference electrode with respect to the amount of charge added to the reference electrode. To determine the reference electrode SOC based at least in part on the anode reference voltage and the amount of charge added to the reference electrode, the controller is further programmed to determine the reference electrode SOC to be less than or equal to the predetermined low SOC threshold in response to determining that the second order reference electrode voltage slope is less than or equal to a predetermined second order reference electrode voltage slope low threshold. To determine the reference electrode SOC based at least in part on the anode reference voltage and the amount of charge added to the reference electrode, the controller is further programmed to determine the reference electrode SOC to be greater than or equal to the predetermined high SOC threshold in response to determining that the second order reference electrode voltage slope is greater than or equal to a predetermined second order reference electrode voltage slope high threshold.

In another aspect of the present disclosure, to adjust the reference electrode SOC, the controller is further programmed to charge the reference electrode in response to determining that the reference electrode SOC is less than or equal to the predetermined low SOC threshold. The reference electrode is charged until the second order reference electrode voltage slope is greater than or equal to the predetermined second order reference electrode voltage slope high threshold.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

FIG. 1 is a schematic of a system for regulating a state of charge of a reference electrode in a battery cell, according to an exemplary embodiment;

FIG. 2 is a schematic diagram of the reference electrode, according to an exemplary embodiment;

FIG. 3 is a schematic diagram of a reference electrode management system, according to an exemplary embodiment;

FIG. 4 is a flowchart of a method for regulating a state of charge of a reference electrode in a battery cell, according to an exemplary embodiment;

FIG. 5 is a flowchart of a first method for determining a reference electrode state of charge, according to an exemplary embodiment;

FIG. 6 is a flowchart of a first method for determining the reference electrode state of charge based on an anode reference voltage and an amount of charge added during charging, according to an exemplary embodiment;

FIG. 7 is a first exemplary graph showing an exemplary first order reference voltage slope, according to an exemplary embodiment;

FIG. 8 is a flowchart of a second method for determining the reference electrode state of charge based on the anode reference voltage and the amount of charge added during charging, according to an exemplary embodiment;

FIG. 9 is a second exemplary graph with an exemplary second order reference voltage slope, according to an exemplary embodiment;

FIG. 10 is a flowchart of a second method for determining the reference electrode state of charge, according to an exemplary embodiment;

FIG. 11 is a flowchart of a method for charging the reference electrode, according to an exemplary embodiment;

FIG. 12 is a flowchart of a method for discharging the reference electrode, according to an exemplary embodiment; and

FIG. 13 is a schematic diagram of an exemplary vehicle shown with the system of FIG. 1, an electrical load, and a battery management system, according to an exemplary embodiment.

### DETAILED DESCRIPTION

The following description is merely exemplary in nature and is not intended to limit the present disclosure, application, or uses.

In aspects of the present disclosure, it is advantageous to accurately and reliably estimate a state of charge of a battery cell. State of charge estimation may depend on measurement of voltages within the battery cell. Thus, battery cells may include a reference electrode to provide a reference voltage for measurement of specific voltage potentials within the battery cell. However, a state of charge of the reference electrode may become depleted during use, degrading performance. Accordingly, the present disclosure provides a new and improved system and method for regulating a state of charge of a reference electrode in a battery cell.

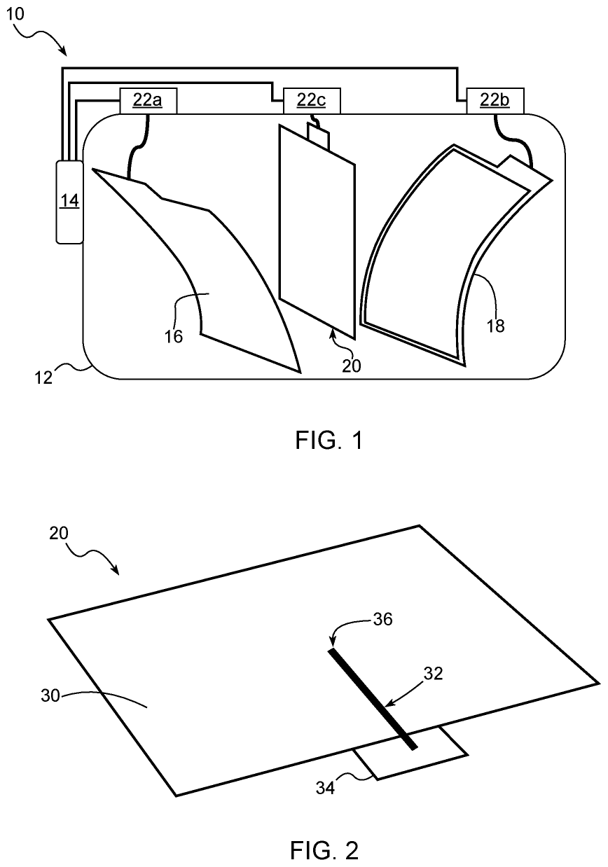

Referring to FIG. 1, a schematic of a system 10 for regulating a state of charge of a reference electrode in a battery cell is shown. The system 10 generally includes a battery cell 12 and a reference electrode management system 14.

The battery cell 12 is used to store electrical energy in the form of chemical energy. In an exemplary embodiment, the battery cell 12 is a Lithium-Ion battery cell (e.g., a Lithium Cobalt Oxide (LiCoO2) battery cell, a Lithium Manganese Oxide (LiMn2O4) battery cell, a Lithium Iron Phosphate (LiFePO4) battery cell, a Lithium Nickel Cobalt Aluminum Oxide (LiNiCoAlO2 or NCA) battery cell, a Lithium Nickel Manganese Cobalt Oxide (LiNiMnCoO2 or NMC) battery cell, a Lithium Titanate (Li4Ti5O12) battery cell, and/or the like). It should be understood that the battery cell 12 may utilize other cell chemistries besides Lithium-Ion without departing from the scope of the present disclosure. In an exemplary embodiment, the battery cell 12 includes a cathode 16, an anode 18, a reference electrode 20 disposed between the cathode 16 and the anode 18, and an electrolyte (not shown) in contact with the cathode 16, the anode 18, and the reference electrode 20.

In a non-limiting example, the cathode 16 is made of a mixed metal oxide of lithium, nickel, manganese, and cobalt. In a non-limiting example, the anode 18 is made of graphite. In a non-limiting example, the electrolyte includes a lithium salt dissolved in a solvent (e.g., Lithium hexafluorophosphate (LiPF6), Lithium bis(trifluoromethanesulfonyl) imide (LiTFSI), Lithium perchlorate (LiClO4), and/or the like). The composition of the reference electrode 20 will be discussed in greater detail below.

In an exemplary embodiment, the cathode 16 is electrically connected to a positive terminal 22a of the battery cell 12. The anode 18 is electrically connected to a negative terminal 22b of the battery cell 12. The reference electrode 20 is electrically connected to a reference terminal 22c of the battery cell 12. The positive terminal 22a, negative terminal 22b, and reference terminal 22c allow the battery cell 12 to be connected to other systems for the purpose of measuring one or more states of the battery cell 12 and/or providing power to an external device, as will be discussed in greater detail below. The reference terminal 22c provides a reference electrode voltage used for measurement of a cathode reference voltage measured between the positive terminal 22a and the reference terminal 22c and/or an anode reference voltage measured between the negative terminal 22b and the reference terminal 22c, as will be discussed in greater detail below.

In the scope of the present disclosure, a state of charge (SOC) generally refers to an amount or concentration of lithium ions intercalated within a lithium ion intercalation material (i.e., a material capable of intercalating lithium ions) relative to a maximum capacity of the lithium ion intercalation material to intercalate lithium ions. A state of charge (SOC) of the battery cell 12 quantifies a present level of charge stored in the battery cell 12 relative to a maximum charge capacity of the battery cell 12. On a molecular level, the SOC of the battery cell 12 refers to the distribution of lithium ions between the cathode 16 and the anode 18. More particularly, the SOC of the battery cell 12 quantifies an amount or concentration of lithium ions intercalated within the anode 18 relative to a maximum capacity of the anode 18 to intercalate lithium ions. In a non-limiting example, when the battery cell 12 is fully charged (i.e., the SOC of the battery cell 12 is 100%), the anode 18 is fully intercalated with lithium ions. As the battery cell 12 discharges, lithium ions move from the anode 18 to the cathode 16 through the electrolyte, resulting in a decrease in the concentration of lithium ions in the anode 18 and an increase in the concentration of lithium ions in the cathode 16, thus decreasing the SOC of the battery cell 12.

Over charging or over discharging the battery cell 12 may damage components of the battery cell 12 such as the cathode 16 and/or the anode 18, resulting in a reduction of an overall usable life of the battery cell 12. Therefore, it is advantageous to determine the SOC of the battery cell 12 for the purposes of battery management. Generally, the SOC of the battery cell 12 is not a directly measurable quantity, and instead must be estimated using a mathematical model of the electrochemical processes occurring within the battery cell 12. In a non-limiting example, the mathematical model is configured to determine or estimate the SOC of the battery cell 12 based at least in part on an open circuit voltage (OCV) of the battery cell 12. In another non-limiting example, the mathematical model is configured to determine or estimate the SOC of the battery cell 12 based at least in part on the cathode reference voltage measured between the positive terminal 22a and the reference terminal 22c and/or the anode reference voltage measured between the negative terminal 22b and the reference terminal 22c.

Referring to FIG. 2, a schematic diagram of the reference electrode 20 is shown. In an exemplary embodiment, the reference electrode 20 includes a separator sheet 30 that holds a reference strip 32 in place. In a non-limiting example, the separator sheet 30 is made of a thin, porous, electrically insulating material which allows the flow of lithium ions while preventing electrical shorts (e.g., polyethylene (PE), polypropylene (PP), and/or the like). The reference strip 32 includes a conductive strip 34 connected to a reference material 36. In a non-limiting example, the reference strip 32 is a flexible structure made of a metal foil (e.g., copper, aluminum, and/or the like) or a polymer film (e.g., polyimide, polyethylene terephthalate, and/or the like). The conductive strip 34 is used to provide an electrical connection between the reference material 36 and the reference terminal 22c. In a non-limiting example, the conductive strip 34 is made of a conductive material (e.g., gold, silver, platinum, copper, and/or the like).

The reference material 36 is an active material which determines the reference electrode voltage of the reference electrode 20. In a non-limiting example, the reference material 36 is made of a lithium compound which has a relatively stable and relatively reproductible electrochemical potential over a relatively wide range of lithium concentration. For example, the reference material 36 may include lithium iron phosphate (LiFePO4), lithium titanate (Li4Ti5O12), lithium cobalt oxide (LiCoO2), and/or the like). As discussed above, a state of charge (SOC) generally refers to an amount or concentration of lithium ions intercalated within a lithium ion intercalation material (i.e., a material capable of intercalating lithium ions) relative to a maximum capacity of the lithium ion intercalation material to intercalate lithium ions. Therefore, in the scope of the present disclosure, a reference electrode SOC is defined as an amount or concentration of lithium ions intercalated within the reference material 36 relative to a maximum capacity of the reference material 36 to intercalate lithium ions.

While the reference electrode voltage of the reference electrode 20 is ideally stable over a wide range of lithium concentration (i.e., reference electrode SOC), variations in the reference electrode SOC may result in variations in the reference electrode voltage, decreasing the accuracy of cathode reference voltage and/or the anode reference voltage measurements. In a non-limiting example, variations in the reference electrode SOC may be caused by electrochemical reactions (also referred to as side reactions) occurring within the battery cell 12. In another non-limiting example, variations in the reference electrode SOC may be caused by charge and/or discharge of the reference electrode material induced by external measurement circuitry in the process of conducting measurements of the cathode reference voltage and/or the anode reference voltage. Therefore, it is advantageous to regulate the reference electrode SOC and maintain the reference electrode SOC within a known and/or ideal range, as will be discussed in greater detail below.

Referring again to FIG. 1, the reference electrode management system 14 is used to regulate the reference electrode SOC. As shown in FIG. 1, the reference electrode management system 14 is in electrical communication with the positive terminal 22a, the negative terminal 22b, and the reference terminal 22c. In an exemplary embodiment, the reference electrode management system 14 is affixed to the battery cell 12, such that the reference electrode management system 14 may operate even when the battery cell 12 is not installed in another device or module (e.g., a battery pack). While the reference electrode management system 14 is depicted in FIG. 1 as being affixed to an outer casing of the battery cell 12, it should be understood that the reference electrode management system 14 may be integrated into the outer casing of the battery cell 12, located within the battery cell 12 with internal connections to the cathode 16, anode 18, and reference electrode 20, or otherwise integral with the battery cell 12 without departing from the scope of the present disclosure.

In another exemplary embodiment, the reference electrode management system 14 is a modular component configured to be easily installable, removable, and replaceable on the battery cell 12. In another exemplary embodiment, the reference electrode management system 14 is located remotely from the battery cell 12 and is electrically connected to the battery cell 12. In another exemplary embodiment, the reference electrode management system 14 is configured to regulate the reference electrode SOC of a plurality of battery cells as part of a battery system (e.g., a multi-cell battery module/pack) and is electrically connected with the plurality of battery cells.

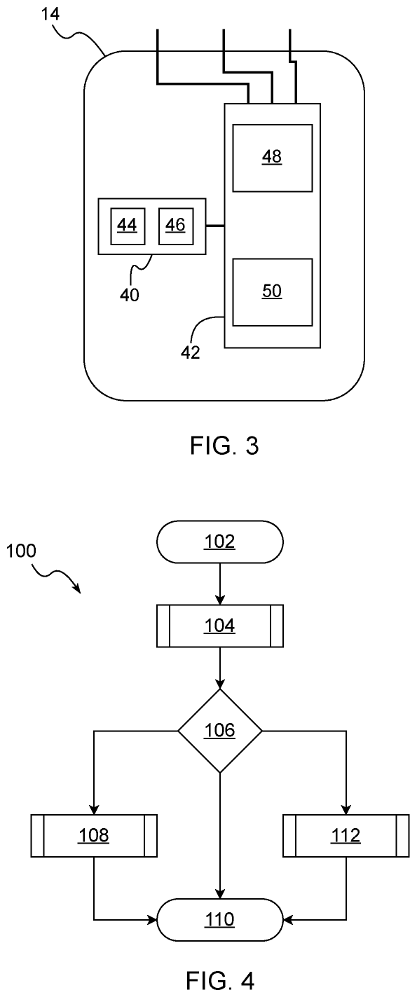

Referring to FIG. 3, a schematic diagram of the reference electrode management system 14 is shown. In an exemplary embodiment, the reference electrode management system 14 includes at least a controller 40 and an interface circuit 42.

The controller 40 is used to implement a method 100 for regulating a state of charge of a reference electrode in a battery cell, as will be described below. The controller 40 includes at least one processor 44 and a non-transitory computer readable storage device or media 46. The processor 44 may be a custom made or commercially available processor, a central processing unit (CPU), a graphics processing unit (GPU), an auxiliary processor among several processors associated with the controller 40, a semiconductor-based microprocessor (in the form of a microchip or chip set), a macroprocessor, a field programmable gate array (FPGA), an application specific integrated circuit (ASIC), a combination thereof, or generally a device for executing instructions.

The computer readable storage device or media 46 may include volatile and nonvolatile storage in read-only memory (ROM), random-access memory (RAM), and keep-alive memory (KAM), for example. KAM is a persistent or non-volatile memory that may be used to store various operating variables while the processor 44 is powered down. The computer-readable storage device or media 46 may be implemented using a number of memory devices such as PROMs (programmable read-only memory), EPROMs (electrically PROM), EEPROMs (electrically erasable PROM), flash memory, or another electric, magnetic, optical, or combination memory devices capable of storing data, some of which represent executable instructions used by the controller 40 to control the reference electrode management system 14. The controller 40 may also consist of multiple controllers which are in electrical communication with each other. The controller 40 further may include additional elements and/or modules, such as, for example, a real-time clock (RTC) module for measuring the passage of real-time. In an exemplary embodiment, the controller 40 is powered by connection to the positive terminal 22a and the negative terminal 22b of the battery cell 12.

The controller 40 is in electrical communication with the interface circuit 42. In an exemplary embodiment, the electrical communication is established using, for example, general purpose input/output (GPIO) pins, an inter-integrated circuit (I2C) bus, a serial peripheral interface (SPI) bus, a parallel communication bus, or the like. It should be understood that various additional communication protocols for communicating with the controller 40 are within the scope of the present disclosure.

The interface circuit 42 is used to interface the controller 40 with the positive terminal 22a, the negative terminal 22b, and the reference terminal 22c. In an exemplary embodiment, the interface circuit 42 includes a measurement circuit 48 and a charging circuit 50.

The measurement circuit 48 is used to measure the anode reference voltage, the cathode reference voltage, and a current flow into/out of the reference electrode 20. In a non-limiting example, the measurement circuit 48 includes, for example an analog to digital converter (ADC). The measurement circuit 48 further may include additional components to support voltage measurement, including, for example, a voltage follower, an input buffer, a multiplexer, and/or the like. The measurement circuit 48 further includes components allowing the controller 40 to measure the current flow into/out of the reference electrode 20, including, for example, a shunt resistor, an electromagnetic current sensor, an ADC, and/or the like.

The charging circuit 50 is used to charge and/or discharge the reference electrode 20. In an exemplary embodiment, the charging circuit 50 includes switching electronics allowing the controller 40 to connect and disconnect the reference terminal 22c between the positive terminal 22a or the negative terminal 22b to charge or discharge the reference electrode 20. In a non-limiting example, the charging circuit 50 includes, for example, relays, contractors, transistors, and/or the like. It should be understood that the measurement circuit 48 and/or the charging circuit 50 of the interface circuit 42 further may include additional passive or active analog and/or digital electronics such as, for example, resistors, capacitors, inductors, filters, amplifiers, power electronics, digital to analog converters (DAC), and/or the like. In an exemplary embodiment, the interface circuit 42 is powered by connection to the positive terminal 22a and the negative terminal 22b of the battery cell 12. The interface circuit 42 is in electrical communication with the controller 40 as discussed above.

Referring to FIG. 4, a flowchart of the method 100 for regulating a state of charge of a reference electrode in a battery cell is shown. The method 100 begins at block 102 and proceeds to block 104. At block 104, the controller 40 determines the reference electrode SOC of the reference electrode 20. Methods for determining the reference electrode SOC will be discussed in greater detail below. After block 104, the method 100 proceeds to block 106.

At block 106, the controller 40 compares the reference electrode SOC determined at block 104 to a predetermined low SOC threshold (e.g., 10%) and a predetermined high SOC threshold (e.g., 90%). If the reference electrode SOC is less than or equal to the predetermined low SOC threshold, the method 100 proceeds to block 108. If the reference electrode SOC is greater than the predetermined low SOC threshold and less than the predetermined high SOC threshold, the method 100 proceeds to enter a standby state at block 110. If the reference electrode SOC is greater than or equal to the predetermined high SOC threshold, the method 100 proceeds to block 112, as will be discussed in greater detail below.

At block 108, the controller 40 uses the interface circuit 42 to charge the reference electrode 20 to adjust the reference electrode SOC in response to determining that the reference electrode SOC is less than or equal to the predetermined low SOC threshold. Methods for charging the reference electrode 20 will be discussed in greater detail below. After block 108, the method 100 proceeds to enter the standby state at block 110.

At block 112, the controller 40 uses the interface circuit 42 to discharge the reference electrode 20 to adjust the reference electrode SOC in response to determining that the reference electrode SOC is greater than or equal to the predetermined high SOC threshold. Methods for discharging the reference electrode 20 will be discussed in greater detail below. After block 112, the method 100 proceeds to enter the standby state at block 110.

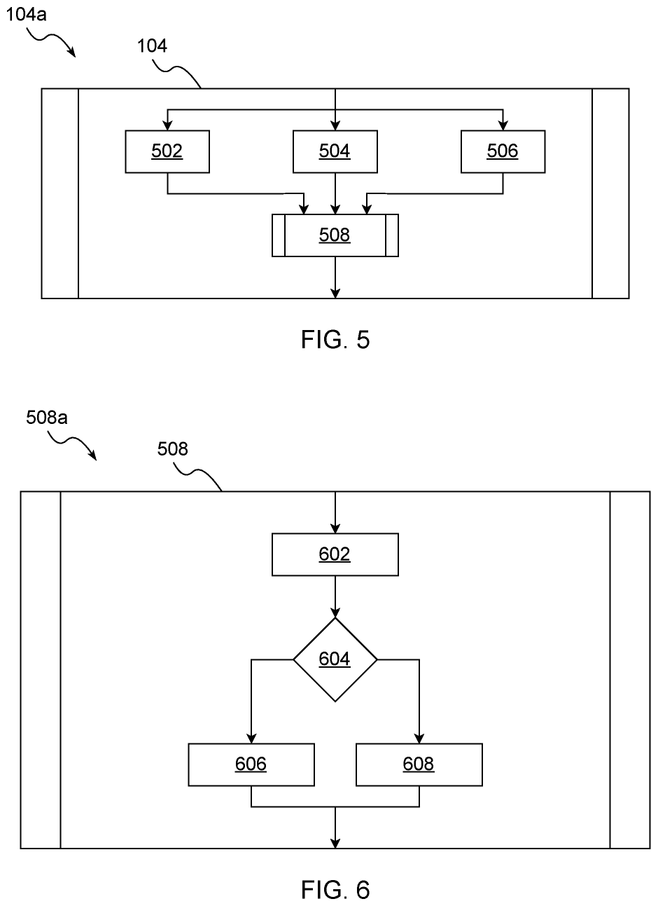

Referring to FIG. 5, a flowchart of a first exemplary embodiment 104a of block 104 of the method 100 (i.e., a first method for determining the reference electrode SOC) is shown. The first exemplary embodiment 104a begins at blocks 502, 504, and 506. At block 502, the controller 40 uses the interface circuit 42 to charge the reference electrode 20. In an exemplary embodiment, to charge the reference electrode 20, the controller 40 uses the charging circuit 50 to connect the positive terminal 22a to the reference terminal 22c allowing flow of current from the cathode 16 to the reference electrode 20. In an exemplary embodiment, the charging circuit 50 allows current flow for a predetermined duration. In a non-limiting example, the predetermined duration depends at least in part on a cross-sectional area and/or a volume of the reference electrode 20. In another exemplary embodiment, the charging circuit 50 allows current to flow until the reference electrode SOC has increased by a predetermined amount (e.g., five percent). After block 502, the first exemplary embodiment 104a proceeds to block 508, as will be discussed in greater detail below.

At block 504, the controller 40 uses the measurement circuit 48 to measure the current flow into the reference electrode 20 during charging at block 502. Based on the predetermined duration, the controller 40 determines an amount of charge added to the reference electrode 20 during charging at block 502. After block 504, the first exemplary embodiment 104a proceeds to block 508, as will be discussed in greater detail below.

At block 506, the controller 40 uses the measurement circuit 48 to measure the anode reference voltage during charging at block 502. After block 506, the first exemplary embodiment 104a proceeds to block 508.

At block 508, the controller 40 determines the reference electrode SOC based at least in part on the anode reference voltage during charging and the amount of charge added to the reference electrode 20 during charging. Methods for determining the reference electrode SOC based at least in part on the anode reference voltage during charging and the amount of charge added to the reference electrode 20 during charging are discussed in greater detail below. After block 508, the first exemplary embodiment 104a is concluded, and the method 100 proceeds as discussed above.

Referring to FIG. 6, a flowchart of a first exemplary embodiment 508a of block 508 of the first exemplary embodiment 104a of block 104 of the method 100 (i.e., a first method for determining the reference electrode SOC based on anode reference voltage and amount of charge added during charging) is shown. The first exemplary embodiment 508a begins at block 602. At block 602, the controller 40 calculates a first order reference electrode voltage slope. In the scope of the present disclosure, the first order reference electrode voltage slope is a first derivative of the anode reference voltage while charging the reference electrode 20 (as determined at block 506) with respect to the amount of charge added to the reference electrode 20 (as determined at block 508).

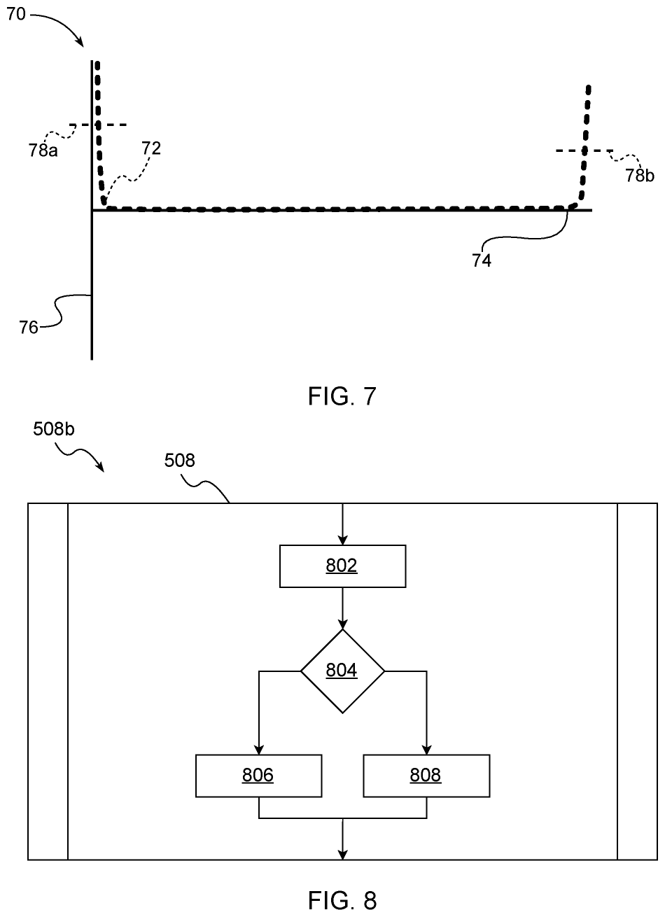

Referring to FIG. 7, a first exemplary graph 70 with an exemplary first order reference voltage slope 72 determined over a range of reference electrode SOCs is shown. An x-axis 74 of the first exemplary graph 70 represents the reference electrode SOC. A y-axis 76 of the first exemplary graph 70 represents a value of the first order reference voltage slope. A first dashed line of the first exemplary graph 70 represents a predetermined first order reference electrode voltage slope low threshold 78a. A second dashed line of the first exemplary graph 70 represents a predetermined first order reference electrode voltage slope high threshold 78b. In an exemplary embodiment, the predetermined first order reference electrode voltage slope low and high thresholds 78a, 78b are chosen based at least in part on the predetermined low SOC threshold and/or the predetermined high SOC threshold.

It should be understood that the exemplary first order reference voltage slope 72 is exemplary in nature and that the shape and values of the first order reference electrode voltage slope may vary based on, for example, application specific characteristics of the reference electrode 20 and/or the battery cell 12. It should further be understood that the value of the predetermined first order reference electrode voltage slope low and high thresholds 78a, 78b shown in the first exemplary graph 70 are merely exemplary in nature. In some embodiments, the predetermined first order reference electrode voltage slope low and high thresholds 78a, 78b may be equal in value. Furthermore, the first exemplary graph 70, the predetermined first order reference electrode voltage slope low and high thresholds 78a, 78b, and the exemplary first order reference voltage slope 72 are not necessarily to scale.

Referring again to FIG. 6 and with continued reference to FIG. 7, after block 602, the first exemplary embodiment 508a proceeds to block 604. At block 604, the controller 40 compares the first order reference electrode voltage slope determined at block 602 to the predetermined first order reference electrode voltage slope low and high thresholds 78a, 78b. If the first order reference electrode voltage slope determined at block 602 is greater than or equal to the predetermined first order reference electrode voltage slope low threshold 78a and decreasing as charge is added to the reference electrode 20, the first exemplary embodiment 508a proceeds to block 606. If the first order reference electrode voltage slope determined at block 602 is greater than or equal to the predetermined first order reference electrode voltage slope high threshold 78b and increasing as charge is added to the reference electrode 20, the first exemplary embodiment 508a proceeds to block 608, as will be discussed in greater detail below.

At block 606, the reference electrode SOC is determined to be less than or equal to the predetermined low SOC threshold in response to determining that the first order reference electrode voltage slope determined at block 602 is greater than or equal to the predetermined first order reference electrode voltage slope low threshold 78a and decreasing as charge is added to the reference electrode 20. After block 606, the first exemplary embodiment 508a is concluded, and the first exemplary embodiment 104a proceeds as discussed above.

At block 608, the reference electrode SOC is determined to be greater than or equal to the predetermined high SOC threshold in response to determining that the first order reference electrode voltage slope determined at block 602 is greater than or equal to the predetermined first order reference electrode voltage slope high threshold 78b and increasing as charge is added to the reference electrode 20. After block 608, the first exemplary embodiment 508a is concluded, and the first exemplary embodiment 104a proceeds as discussed above.

Referring to FIG. 8, a flowchart of a second exemplary embodiment 508b of block 508 of the first exemplary embodiment 104a of block 104 of the method 100 (i.e., a second method for determining the reference electrode SOC based on anode reference voltage and amount of charge added during charging) is shown. It should be understood that the first exemplary embodiment 508a, the second exemplary embodiment 508b, or any combination thereof may be used to perform block 508 of the first exemplary embodiment 104a in the scope of the present disclosure. The second exemplary embodiment 508b begins at block 802. At block 802, the controller 40 calculates a second order reference electrode voltage slope. In the scope of the present disclosure, the second order reference electrode voltage slope is a second derivative of the anode reference voltage while charging the reference electrode 20 (as determined at block 506) with respect to the amount of charge added to the reference electrode 20 (as determined at block 508).

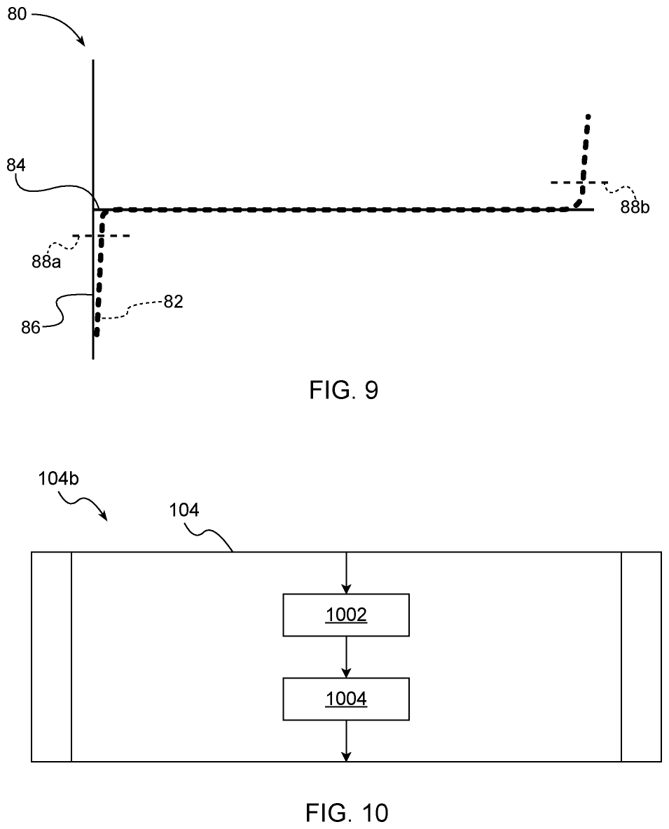

Referring to FIG. 9, a second exemplary graph 80 with an exemplary second order reference voltage slope 82 determined over a range of reference electrode SOCs is shown. An x-axis 84 of the second exemplary graph 80 represents the reference electrode SOC. A y-axis 86 of the second exemplary graph 80 represents a value of the second order reference voltage slope. A first dashed line of the second exemplary graph 80 represents a predetermined second order reference electrode voltage slope low threshold 88a. A second dashed line of the second exemplary graph 80 represents a predetermined second order reference electrode voltage slope high threshold 88b. In an exemplary embodiment, the predetermined second order reference electrode voltage slope low and high thresholds 88a, 88b are chosen based at least in part on the predetermined low SOC threshold and/or the predetermined high SOC threshold.

It should be understood that the exemplary second order reference voltage slope 82 is exemplary in nature and that the shape and values of the second order reference electrode voltage slope may vary based on, for example, application specific characteristics of the reference electrode 20 and/or the battery cell 12. It should further be understood that the value of the predetermined second order reference electrode voltage slope low and high thresholds 88a, 88b shown in the second exemplary graph 80 are merely exemplary in nature. In some embodiments, the predetermined second order reference electrode voltage slope low and high thresholds 88a, 88b may be equal in magnitude. Furthermore, the second exemplary graph 80, the predetermined second order reference electrode voltage slope low and high thresholds 88a, 88b, and the exemplary second order reference voltage slope 82 are not necessarily to scale.

Referring again to FIG. 8 and with continued reference to FIG. 9, after block 802, the second exemplary embodiment 508b proceeds to block 804. At block 804, the controller 40 compares the second order reference electrode voltage slope determined at block 802 to the predetermined second order reference electrode voltage slope low and high thresholds 88a, 88b. If the second order reference electrode voltage slope determined at block 802 is less than or equal to the predetermined second order reference electrode voltage slope low threshold 88a, the second exemplary embodiment 508b proceeds to block 806. If the second order reference electrode voltage slope determined at block 802 is greater than or equal to the predetermined second order reference electrode voltage slope high threshold 88b, the second exemplary embodiment 508b proceeds to block 808, as will be discussed in greater detail below.

At block 806, the reference electrode SOC is determined to be less than or equal to the predetermined low SOC threshold in response to determining that the second order reference electrode voltage slope determined at block 802 is less than or equal to the predetermined second order reference electrode voltage slope low threshold 88a. After block 806, the second exemplary embodiment 508b is concluded, and the first exemplary embodiment 104a proceeds as discussed above.

At block 808, the reference electrode SOC is determined to be greater than or equal to the predetermined high SOC threshold in response to determining that the second order reference electrode voltage slope determined at block 802 is greater than or equal to the predetermined second order reference electrode voltage slope high threshold 88b. After block 808, the second exemplary embodiment 508b is concluded, and the first exemplary embodiment 104a proceeds as discussed above.

Referring to FIG. 10, a flowchart of a second exemplary embodiment 104b of block 104 of the method 100 (i.e., a second method for determining the reference electrode SOC) is shown. It should be understood that the first exemplary embodiment 104a, the second exemplary embodiment 104b, or any combination thereof may be used to perform block 104 of the method 100 in the scope of the present disclosure. The second exemplary embodiment 104b begins at block 1002. At block 1002, the controller 40 tracks an elapsed time since the reference electrode 20 was previously charged (i.e., an elapsed time since a previous execution of block 108 of the method 100). In an exemplary embodiment, the controller 40 uses a real-time clock (RTC) module to track the elapsed time. After block 1002, the second exemplary embodiment 104b proceeds to block 1004.

At block 1004, the controller 40 calculates the reference electrode SOC. In an exemplary embodiment, the controller 40 first calculates an amount of lost charge lost from the reference electrode 20 over the elapsed time determined at block 1002. In a non-limiting example, the controller 40 multiplies the elapsed time by a predetermined reference electrode discharge rate of the reference electrode. In the scope of the present disclosure, the predetermined reference electrode discharge rate quantifies an amount of charge lost from the reference electrode 20 per unit of time during normal operation of the reference electrode management system 14. In an exemplary embodiment, the predetermined reference electrode discharge rate is determined using computer simulation and/or physical experimentation. The predetermined reference electrode discharge rate is then saved in the media 46 of the controller 40 for use during the second exemplary embodiment 104b.

The controller 40 then calculates the reference electrode SOC based on the amount of lost charge. In an exemplary embodiment, the reference electrode SOC is proportional to a previous amount of charge on the reference electrode 20 (as determined, for example, based on the previous charging process of the reference electrode 20 using the measurement circuit 48 of the interface circuit 42) minus the amount of lost charge. After block 1004, the second exemplary embodiment 104b is concluded, and the method 100 proceeds as discussed above.

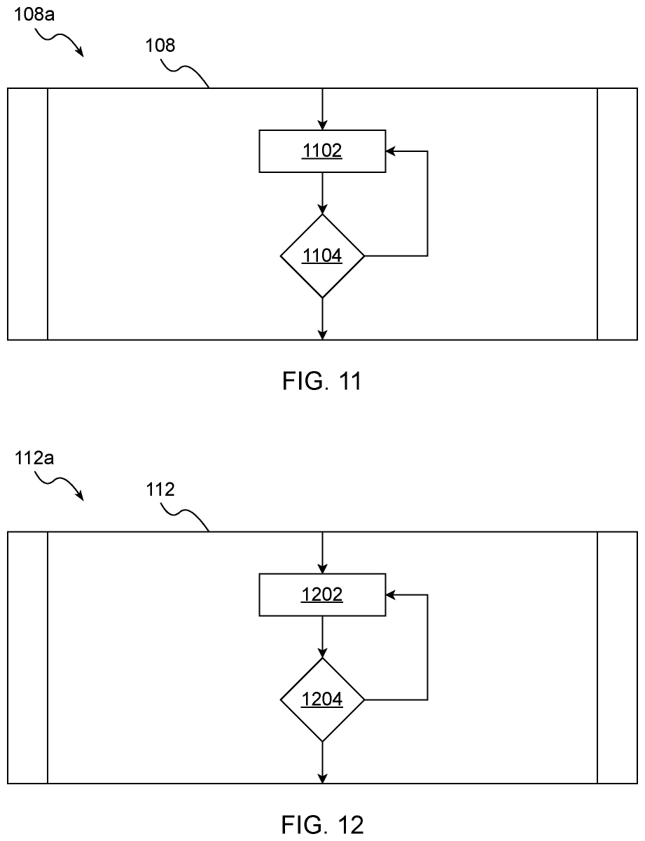

Referring to FIG. 11, a flowchart of an exemplary embodiment 108a of block 108 of the method 100 (i.e., a method for charging the reference electrode 20) is shown. The exemplary embodiment 108a begins at block 1102. At block 1102, the controller 40 charges the reference electrode 20. In an exemplary embodiment, to charge the reference electrode 20, the controller 40 uses the charging circuit 50 of the interface circuit 42 to connect the positive terminal 22a (i.e., the cathode 16) to the reference terminal 22c (i.e., the reference electrode 20), allowing current to flow into the reference electrode 20. In an exemplary embodiment, the controller 40 concurrently uses the measurement circuit 48 to measure a magnitude of the current flow into the reference electrode 20 over time for purposes of calculation of charge added to the reference electrode 20. The controller 40 also uses the measurement circuit 48 to measure the anode reference voltage while charging the reference electrode 20. After block 1102, the exemplary embodiment 108a proceeds to block 1104.

At block 1104, the controller 40 evaluates a charging stopping condition. In a first exemplary embodiment, the charging stopping condition is satisfied when the first order reference electrode voltage slope (as determined using the method described in reference to the first exemplary embodiment 508a of block 508 of the first exemplary embodiment 104a of block 104 of the method 100) is greater than or equal to the predetermined first order reference electrode voltage slope high threshold 78b and the first order reference electrode voltage slope is increasing. In other words, the charging stopping condition is satisfied when the reference electrode SOC reaches the predetermined high SOC threshold.

In a second exemplary embodiment, the charging stopping condition is satisfied when the second order reference electrode voltage slope (as determined using the method described in reference to the second exemplary embodiment 508b of block 508 of the first exemplary embodiment 104a of block 104 of the method 100) is greater than or equal to the predetermined second order reference electrode voltage slope high threshold 88b. In other words, the charging stopping condition is satisfied when the reference electrode SOC reaches the predetermined high SOC threshold.

In a third exemplary embodiment, the charging stopping condition is satisfied when the amount of lost charge (as determined using the method described in reference to the second exemplary embodiment 104b of block 104 of the method 100) is returned to the reference electrode 20. If the charging stopping condition is not satisfied, the exemplary embodiment 108a returns to block 1102 to continue charging the reference electrode 20. If the charging stopping condition is satisfied, the exemplary embodiment 108a is concluded, and the method 100 proceeds as described above.

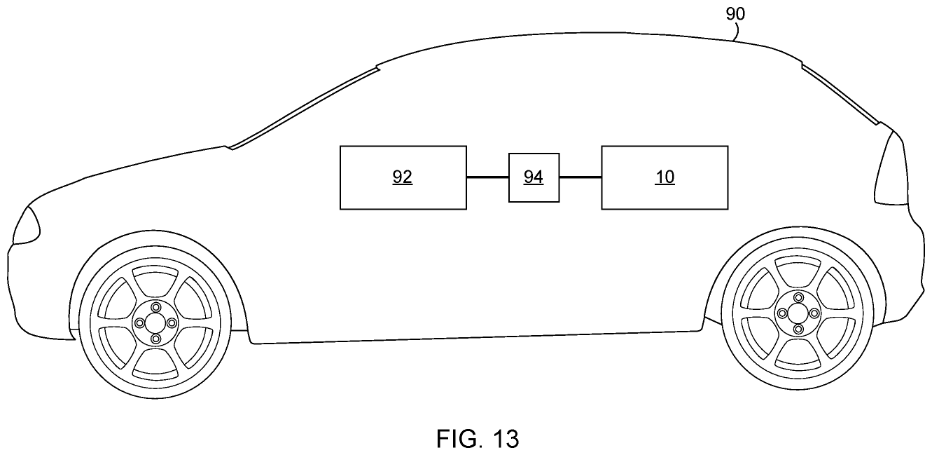

Referring to FIG. 12, a flowchart of an exemplary embodiment 112a of block 112 of the method 100 (i.e., a method for discharging the reference electrode 20) is shown. The exemplary embodiment 112a begins at block 1202. At block 1202, the controller 40 discharges the reference electrode 20. In an exemplary embodiment, to discharge the reference electrode 20, the controller 40 uses the charging circuit 50 of the interface circuit 42 to connect the negative terminal 22b (i.e., the anode 18) to the reference terminal 22c (i.e., the reference electrode 20), allowing current to flow out of the reference electrode 20. In an exemplary embodiment, the controller 40 concurrently uses the measurement circuit 48 to measure a magnitude of the current flow out of the reference electrode 20 over time for purposes of calculation of charge removed from the reference electrode 20. The controller 40 also uses the measurement circuit 48 to measure the anode reference voltage while discharging the reference electrode 20. After block 1202, the exemplary embodiment 112a proceeds to block 1204.

At block 1204, the controller 40 evaluates a discharging stopping condition. In a first exemplary embodiment, the discharging stopping condition is satisfied when the first order reference electrode voltage slope (as determined using the method described in reference to the first exemplary embodiment 508a of block 508 of the first exemplary embodiment 104a of block 104 of the method 100) is greater than or equal to the predetermined first order reference electrode voltage slope high threshold 78b and the first order reference electrode voltage slope is increasing. In other words, the discharging stopping condition is satisfied when the reference electrode SOC reaches the predetermined high SOC threshold.

In a second exemplary embodiment, the discharging stopping condition is satisfied when the second order reference electrode voltage slope (as determined using the method described in reference to the second exemplary embodiment 508b of block 508 of the first exemplary embodiment 104a of block 104 of the method 100) is greater than or equal to the predetermined second order reference electrode voltage slope high threshold 88b. In other words, the discharging stopping condition is satisfied when the reference electrode SOC reaches the predetermined high SOC threshold. If the discharging stopping condition is satisfied, the exemplary embodiment 112a is concluded, and the method 100 proceeds as described above.

Referring to FIG. 13, an exemplary vehicle 90 is shown with the system 10, an electrical load 92, and a battery management system 94. The electrical load 92 and the battery management system 94 are in electrical communication with the system 10. In an exemplary embodiment, the electrical load 92 includes electrical and/or electromechanical components or systems of the vehicle 90 which require electrical energy for operation. In a non-limiting example, the electrical load 92 includes the battery management system 94, a vehicle controller, an infotainment system, one or more vehicle lights, a vehicle propulsion system including an electric motor, and/or the like. The battery cell 12 of the system 10 is configured to provide electrical energy to the electrical load 92.

The battery management system 94 is used to monitor the battery cell 12, provide information about a state of the battery cell 12 to external systems (e.g., the vehicle controller), and optimize use of the battery cell 12 to prolong a usable life of the battery cell 12 and protect the battery cell 12 from damage. In an exemplary embodiment, the battery management system 94 facilitates the electrical connection between the system 10 and the electrical load 92 and may disconnect the system 10 from the electrical load 92 for protection of the battery cell 12. In an exemplary embodiment, the battery management system 94 performs measurements of the anode reference voltage and/or the cathode reference voltage (using, for example, the measurement circuit 48 of the interface circuit 42 of the reference electrode management system 14) and executes a mathematical model to estimate the SOC of the battery cell 12. The SOC of the battery cell 12 is used by other vehicle systems (e.g., the vehicle controller) to provide vehicle range and/or battery status information to an occupant of the vehicle 90.

The system 10 and method 100 of the present disclosure offer several advantages. Using the first exemplary embodiment 104a of block 104 of the method 100 (i.e., the first method for determining the reference electrode SOC), the reference electrode SOC may be determined regardless of the SOC of the battery cell 12. Therefore, the reference electrode SOC may be monitored and adjusted frequently to prevent over discharging of the reference electrode 20. Using the second exemplary embodiment 104b of block 104 of the method 100 (i.e., the second method for determining the reference electrode SOC), the reference electrode SOC may be determined regardless of the SOC of the battery cell 12 and regardless of an equilibrium state of the battery cell 12 (i.e., when the battery cell 12 is under any load condition). Therefore, the reference electrode SOC may be monitored and adjusted frequently to prevent over discharging of the reference electrode 20, even when the battery cell 12 is under frequent load. In an exemplary embodiment, the first exemplary embodiment 104a and the second exemplary embodiment 104b are used in combination to provide a balance between accuracy and frequency of measurement of the reference electrode SOC. Furthermore, by providing the reference electrode management system 14 affixed to or otherwise integral with the battery cell 12, the reference electrode management system 14 may operate to regulate the reference electrode SOC even if the battery cell 12 is not installed in a host application (e.g., if the battery cell 12 is in storage or transport), prolonging a usable life of the reference electrode 20 and the battery cell 12.

The description of the present disclosure is merely exemplary in nature and variations that do not depart from the gist of the present disclosure are intended to be within the scope of the present disclosure. Such variations are not to be regarded as a departure from the spirit and scope of the present disclosure.

What is claimed is:

1. A method for regulating a state of charge of a reference electrode in a battery cell, the method comprising:
determining a reference electrode state of charge (SOC) of the reference electrode, wherein the battery cell includes an anode, a cathode, and the reference electrode, and wherein the reference electrode is disposed between the anode and the cathode;
comparing the reference electrode SOC to at least a predetermined low SOC threshold; and
adjusting the reference electrode SOC in response to determining that the reference electrode SOC is less than or equal to the predetermined low SOC threshold or that the reference electrode SOC is greater than or equal to a predetermined high SOC threshold.

2. The method of claim 1, wherein determining the reference electrode SOC further comprises:
charging the reference electrode and measuring an amount of charge added to the reference electrode;
measuring an anode reference voltage while charging the reference electrode; and
determining the reference electrode SOC based at least in part on the anode reference voltage and the amount of charge added to the reference electrode.

3. The method of claim 2, wherein determining the reference electrode SOC based at least in part on the anode reference voltage and the amount of charge added to the reference electrode further comprises:
calculating a first order reference electrode voltage slope, wherein the first order reference electrode voltage slope is a first derivative of the anode reference voltage while charging the reference electrode with respect to the amount of charge added to the reference electrode; and
determining the reference electrode SOC based at least in part on the first order reference electrode voltage slope.

4. The method of claim 3, wherein determining the reference electrode SOC based at least in part on the first order reference electrode voltage slope further comprises:
determining the reference electrode SOC to be less than or equal to the predetermined low SOC threshold in response to determining that the first order reference electrode voltage slope is greater than or equal to a predetermined first order reference electrode voltage slope low threshold and that the first order reference electrode voltage slope is decreasing; and
determining the reference electrode SOC to be greater than or equal to the predetermined high SOC threshold in response to determining that the first order reference electrode voltage slope is greater than or equal to the predetermined first order reference electrode voltage slope high threshold and that the first order reference electrode voltage slope is increasing.

5. The method of claim 4, wherein adjusting the reference electrode SOC further comprises:
charging the reference electrode in response to determining that the reference electrode SOC is less than or equal to the predetermined low SOC threshold, wherein the reference electrode is charged until the first order reference electrode voltage slope is greater than or equal to the predetermined first order reference electrode voltage slope high threshold and the first order reference electrode voltage slope is increasing.

6. The method of claim 2, wherein determining the reference electrode SOC based at least in part on the anode reference voltage and the amount of charge added to the reference electrode further comprises:
calculating a second order reference electrode voltage slope, wherein the second order reference electrode voltage slope is a second derivative of the anode reference voltage while charging the reference electrode with respect to the amount of charge added to the reference electrode; and
determining the reference electrode SOC based at least in part on the second order reference electrode voltage slope.

7. The method of claim 6, wherein determining the reference electrode SOC based at least in part on the second order reference electrode voltage slope further comprises:
determining the reference electrode SOC to be less than or equal to the predetermined low SOC threshold in response to determining that the second order reference electrode voltage slope is less than or equal to a predetermined second order reference electrode voltage slope low threshold; and
determining the reference electrode SOC to be greater than or equal to the predetermined high SOC threshold in response to determining that the second order reference electrode voltage slope is greater than or equal to a predetermined second order reference electrode voltage slope high threshold.

8. The method of claim 7, wherein adjusting the reference electrode SOC further comprises:
charging the reference electrode in response to determining that the reference electrode SOC is less than or equal to the predetermined low SOC threshold, wherein the reference electrode is charged until the second order reference electrode voltage slope is greater than or equal to the predetermined second order reference electrode voltage slope high threshold.

9. The method of claim 1, wherein determining the reference electrode SOC further comprises:
tracking an elapsed time since a previous charging process of the reference electrode;
calculating an amount of lost charge from the reference electrode based at least in part on the elapsed time and a predetermined reference electrode discharge rate of the reference electrode; and
calculating the reference electrode SOC based at least in part on the amount of lost charge.

10. The method of claim 9, wherein adjusting the reference electrode SOC further comprises:
charging the reference electrode in response to determining that the reference electrode SOC is less than or equal to the predetermined low SOC threshold, wherein the reference electrode is charged until the amount of lost charge is returned to the reference electrode.

11. A system for regulating a state of charge of a reference electrode in a battery cell, the system comprising:
the battery cell including an anode, a cathode, and the reference electrode, wherein the reference electrode is disposed between the anode and the cathode;
a reference electrode management system in electrical communication with the battery cell, the reference electrode management system including a controller, wherein the controller is programmed to:
determine a reference electrode state of charge (SOC) of the reference electrode;
compare the reference electrode SOC to at least a predetermined low SOC threshold; and
adjust the reference electrode SOC in response to determining that the reference electrode SOC is less than or equal to the predetermined low SOC threshold or that the reference electrode SOC is greater than or equal to a predetermined high SOC threshold.

12. The system of claim 11, wherein to determine the reference electrode SOC, the controller is further programmed to:
charge the reference electrode by allowing a current flow between the cathode and the reference electrode;
measure an amount of charge added to the reference electrode while charging the reference electrode;
measure an anode reference voltage while charging the reference electrode; and
determine the reference electrode SOC based at least in part on the anode reference voltage and the amount of charge added to the reference electrode.

13. The system of claim 12, wherein to determine the reference electrode SOC based at least in part on the anode reference voltage and the amount of charge added to the reference electrode, the controller is further programmed to:
calculate a first order reference electrode voltage slope, wherein the first order reference electrode voltage slope is a first derivative of the anode reference voltage while charging the reference electrode with respect to the amount of charge added to the reference electrode;
determine the reference electrode SOC to be less than or equal to the predetermined low SOC threshold in response to determining that the first order reference electrode voltage slope is greater than or equal to a predetermined first order reference electrode voltage slope low threshold and that the first order reference electrode voltage slope is decreasing; and
determine the reference electrode SOC to be greater than or equal to the predetermined high SOC threshold in response to determining that the first order reference electrode voltage slope is greater than or equal to the predetermined first order reference electrode voltage slope high threshold and that the first order reference electrode voltage slope is increasing.

14. The system of claim 13, wherein to determine the reference electrode SOC based at least in part on the anode reference voltage and the amount of charge added to the reference electrode, the controller is further programmed to:
calculate a second order reference electrode voltage slope, wherein the second order reference electrode voltage slope is a second derivative of the anode reference voltage while charging the reference electrode with respect to the amount of charge added to the reference electrode; and
determine the reference electrode SOC to be less than or equal to the predetermined low SOC threshold in response to determining that the second order reference electrode voltage slope is less than or equal to a predetermined second order reference electrode voltage slope low threshold; and
determine the reference electrode SOC to be greater than or equal to the predetermined high SOC threshold in response to determining that the second order reference electrode voltage slope is greater than or equal to a predetermined second order reference electrode voltage slope high threshold.

15. The system of claim 14, wherein to adjust the reference electrode SOC, the controller is further programmed to:
charge the reference electrode in response to determining that the reference electrode SOC is less than or equal to the predetermined low SOC threshold, wherein the reference electrode is charged until at least one of: (i) the first order reference electrode voltage slope is greater than or equal to the predetermined first order reference electrode voltage slope high threshold and the first order reference electrode voltage slope is increasing and (ii) the second order reference electrode voltage slope is greater than or equal to the predetermined second order reference electrode voltage slope high threshold.

16. The system of claim 11, wherein to determine the reference electrode SOC, the controller is further programmed to:
track an elapsed time since a previous charging process of the reference electrode;
calculate an amount of lost charge from the reference electrode based at least in part on the elapsed time and a predetermined reference electrode discharge rate of the reference electrode; and
calculate the reference electrode SOC based at least in part on the amount of lost charge.

17. The system of claim 16, wherein to adjust the reference electrode SOC, the controller is further programmed to:
charge the reference electrode in response to determining that the reference electrode SOC is less than or equal to the predetermined low SOC threshold, wherein the reference electrode is charged until the amount of lost charge is returned to the reference electrode.

18. A system for regulating a state of charge of a reference electrode in a battery cell in a vehicle, the system comprising:
the battery cell including an anode, a cathode, and the reference electrode, wherein the reference electrode is disposed between the anode and the cathode;
a reference electrode management system in electrical communication with the battery cell, the reference electrode management system including a controller, wherein the controller is programmed to:
charge the reference electrode by allowing a current flow between the cathode and the reference electrode;
measure an amount of charge added to the reference electrode while charging the reference electrode;
measure an anode reference voltage while charging the reference electrode;
determine a reference electrode SOC based at least in part on the anode reference voltage and the amount of charge added to the reference electrode;
compare the reference electrode SOC to at least a predetermined low SOC threshold; and
adjust the reference electrode SOC in response to determining that the reference electrode SOC is less than or equal to the predetermined low SOC threshold or that the reference electrode SOC is greater than or equal to a predetermined high SOC threshold.

19. The system of claim 18, wherein to determine the reference electrode SOC based at least in part on the anode reference voltage and the amount of charge added to the reference electrode, the controller is further programmed to:
calculate a second order reference electrode voltage slope, wherein the second order reference electrode voltage slope is a second derivative of the anode reference voltage while charging the reference electrode with respect to the amount of charge added to the reference electrode; and
determine the reference electrode SOC to be less than or equal to the predetermined low SOC threshold in response to determining that the second order reference electrode voltage slope is less than or equal to a predetermined second order reference electrode voltage slope low threshold; and
determine the reference electrode SOC to be greater than or equal to the predetermined high SOC threshold in response to determining that the second order reference electrode voltage slope is greater than or equal to a predetermined second order reference electrode voltage slope high threshold.

20. The system of claim 19, wherein to adjust the reference electrode SOC, the controller is further programmed to:
charge the reference electrode in response to determining that the reference electrode SOC is less than or equal to the predetermined low SOC threshold, wherein the reference electrode is charged until the second order reference electrode voltage slope is greater than or equal to the predetermined second order reference electrode voltage slope high threshold.
